(19) United States
(12) Patent Application Publication
(10) Pub. No.: US 2024/0178056 A1
(43) Pub. Date: May 30, 2024

(54) METHOD FOR TRANSFERRING A LAYER OF A HETEROSTRUCTURE

(71) Applicant: Soitec, BERNIN (FR)

(72) Inventor: Thierry Barge, BERNIN (FR)

(21) Appl. No.: 18/551,346

(22) PCT Filed: Mar. 17, 2022
(86) PCT No.: PCT/FR2022/050478

§ 371 Date: Sep. 19, 2023

(30) Foreign Application Priority Data
Mar. 19, 2021 (FR) FR2102779

(51) Int. Cl. H01L 21/762; H01L 21/18; H01L 21/304

(52) U.S. Cl. CPC H01L 21/76254; H01L 21/187; H01L 21/304

(57) ABSTRACT

A method of transferring a layer from a heterostructure to a receiver substrate comprises the following successive steps: supplying a donor substrate of a first material and a carrier substrate of a second material, bonding the donor substrate to the carrier substrate, thinning the donor substrate, so as to form the heterostructure comprising the thinned donor substrate on the carrier substrate, removing a peripheral portion of the donor substrate, forming a weakened region in the thinned donor substrate so as to delimit a layer of the first material to be transferred, bonding the heterostructure to a receiver substrate, the layer of the first material to be transferred being located at the bonding interface, and detaching the donor substrate along the weakened region so as to transfer the layer of the first material to the receiver substrate.

### CROSS REFERENCE TO RELATED APPLICATIONS

This application is a national phase entry under 35 U.S.C. § 371 of International Patent Application PCT/FR2022/050478, filed Mar. 17, 2022, designating the United States of America and published as International Patent Publication WO 2022/195225 A1 on Sep. 22, 2022, which claims the benefit under Article 8 of the Patent Cooperation Treaty to French Patent Application Serial No. FR2102779, filed Mar. 19, 2021.

### TECHNICAL FIELD

The present disclosure relates to a method for transferring a layer from a heterostructure to a receiver substrate.

### BACKGROUND

In the field of microelectronics, layer transfer methods are used to transfer a layer from a first substrate, called the donor substrate, to a second substrate, called the receiver substrate.

The Smart Cut™ method is thus well known for the production of semiconductor-on-insulator substrates, but also other composite substrates, for example, piezoelectric-on-insulator substrates. This method comprises forming a weakened region by implanting atomic species into the donor substrate, in order to delimit a layer of interest to be transferred, bonding the donor substrate to the receiver substrate, and then detaching the donor substrate along the weakened region, so as to transfer the layer of interest to the receiver substrate.

In some situations, it is not possible to directly transfer a layer from a donor substrate to the receiver substrate, for example, because of constraints related to the transfer method. More particularly, the bonding of the donor substrate to the receiver substrate may be achieved via silicon oxide layers formed beforehand on the surface of each of the two substrates. However, to manage to detach the layer of interest to be transferred, it is necessary to perform an anneal in a temperature range from 100° ° C. to 600° C. When the donor substrate and the receiver substrate have different coefficients of thermal expansion—which is the case, for example, between a donor substrate made of a piezoelectric material and a receiver substrate made of silicon—the anneal results in significant deformation (or “bowing”) of the assembly of the two substrates, which is detrimental to the transfer process in that it may lead to the substrates breaking.

To minimize such deformation, it is possible to form an intermediate substrate called a donor virtual substrate, in which the donor substrate is joined to a temporary carrier substrate.

The transfer method then comprises a prior step of forming the donor virtual substrate by bonding the donor substrate to the carrier substrate, a step of thinning the donor substrate, a step of implanting atomic species into the donor virtual substrate in order to delimit the layer of interest to be transferred, and a step of bonding the donor virtual substrate to the final receiver substrate, and a step of detaching the donor virtual substrate along the weakened region in order to transfer the layer of interest to the receiver substrate.

Application WO 2019/186032 describes such a method adapted for the formation of a piezoelectric-on-insulator substrate.

One problem that arises when producing such a donor virtual substrate is its fragility. Specifically, the substrates used in microelectronics are provided with a peripheral chamfer, which makes it possible to avoid having sharp angles, which are particularly fragile, on the edge of the substrates. Given the thinness of the thinned donor substrate, the substrate has an inclined edge and thus forms a very thin and brittle strip.

However, the debris created by this strip breaking is liable to contaminate the production line and the substrates produced on this line.

### BRIEF SUMMARY

An aim of the present disclosure is therefore to allow the production of a heterostructure (donor virtual substrate) comprising a thinned donor substrate while minimizing the risk of breakage of the donor substrate and the transfer of a layer from the heterostructure to a receiver substrate.

To that end, the present disclosure proposes a method for transferring a layer from a heterostructure to a receiver substrate, comprising the following steps in succession:
providing a donor substrate of a first material and a carrier substrate of a second material,
bonding the donor substrate to the carrier substrate,
thinning the donor substrate, so as to form the heterostructure (H) comprising the thinned donor substrate on the carrier substrate,
the formation of the heterostructure further comprising a step of removing a peripheral portion from the donor substrate,
forming a weakened region in the thinned donor substrate so as to delimit a layer of the first material to be transferred,
bonding the heterostructure to a receiver substrate, the layer of the first material to be transferred being located at the bonding interface,
detaching the donor substrate along the weakened region so as to transfer the layer of the first material to the receiver substrate.

The removal of the peripheral annular portion from the donor substrate (also called “trimming”), which may be performed before or after the bonding of the substrate to the carrier substrate, makes it possible to prevent a brittle strip from being formed.

According to other advantageous but optional features of the method, potentially in combination when this is technically feasible:
the step of removing the peripheral portion from the donor substrate is carried out before the bonding of the donor substrate to the carrier substrate;
the step of removing the peripheral portion from the donor substrate is carried out after the bonding of the donor substrate to the carrier substrate;
the removal of the peripheral portion from the donor substrate further comprises removing a peripheral portion from the carrier substrate facing the donor substrate;
the step of removing the peripheral portion from the donor substrate is carried out after the donor substrate has been at least partly thinned;
the donor substrate is bonded to the carrier substrate via a polymeric bonding layer;
the width of the peripheral portion removed from the donor substrate is between 300 and 1000 μm, preferably between 300 and 500 μm from the edge of the donor substrate;
the donor substrate is bonded to the carrier substrate via molecular adhesion;
the width of the peripheral portion removed from the donor substrate is between 1 and 3 mm, preferably between 2 and 3 mm from the edge of the donor substrate;
the removal of the peripheral portion comprises:
placing the donor substrate on a carrier that is rotatably movable about a first axis;
machining the donor substrate using an abrasive wheel rotating about a second axis parallel to the first axis, the abrasive wheel further being driven in translation along the second axis;
the removal of the peripheral portion comprises:
placing the donor substrate on a carrier that is rotatably movable about a first axis;
machining the donor substrate using an abrasive wheel rotating about a second axis perpendicular to the first axis;
the method further comprises a step of polishing the donor substrate after the removal of the peripheral portion;
the donor substrate comprises a piezoelectric material or a semiconductor material;
the thickness of the thinned donor substrate is between 10 and 100 μm, preferably between 10 and 50 μm;
the carrier substrate comprises silicon, glass, quartz, sapphire, a ceramic, and/or polycrystalline aluminum nitride.

According to other advantageous but optional features of the method, potentially in combination when this is technically feasible:
before the bonding of the heterostructure to the receiver substrate, an intermediate layer is formed on the donor substrate and/or the receiver substrate;
the intermediate layer comprises silicon oxide, silicon nitride, silicon oxynitride, aluminum nitride (AlN), and/or tantalum oxide (Ta₂O₅), or a stack of layers formed of at least two of the materials;
the receiver substrate comprises silicon, glass, quartz, sapphire, a ceramic, and/or polycrystalline aluminum nitride;
the receiver substrate is a silicon substrate including a charge-trapping layer comprising polycrystalline silicon, silicon carbide, amorphous silicon and/or porous silicon;
the carrier substrate and the receiver substrate comprise materials exhibiting a difference in coefficient of thermal expansion smaller than or equal to 5% in terms of absolute value;
the carrier substrate and the receiver substrate are formed of one and the same material;
the transferred layer has a thickness of between 30 nm and 1.5 μm.

### BRIEF DESCRIPTION OF THE DRAWINGS

Further features and advantages of this method will become apparent from the following detailed description, with reference to the appended drawings, in which:

FIG. 1A is a diagram of the assembly of the donor substrate and of the carrier substrate;

FIG. 1B is a diagram of the assembly of the donor substrate and of the carrier substrate, after thinning of the donor substrate;

FIG. 2A schematically illustrates the operation of trimming the donor substrate before bonding to the carrier substrate;

FIG. 2B is a cross-sectional view of the periphery of the heterostructure after the bonding of the trimmed donor substrate of FIG. 2A to the carrier substrate;

FIG. 2C is a cross-sectional view of the periphery of the heterostructure after thinning of the donor substrate;

FIG. 3A schematically illustrates the operation of trimming the donor substrate after bonding and thinning thereof on the carrier substrate;

FIG. 3B is a cross-sectional view of the periphery of the heterostructure after the trimming of FIG. 3A;

FIG. 4A schematically illustrates the operation of trimming the donor substrate after its bonding to the carrier substrate;

FIG. 4B is a cross-sectional view of the periphery of the donor substrate before thinning thereof and of the carrier substrate after the trimming of FIG. 4A;

FIG. 4C is a cross-sectional view of the periphery of the heterostructure after the thinning of the trimmed donor substrate of FIG. 4B;

FIG. 5A schematically illustrates a first embodiment of the trimming;

FIG. 5B schematically illustrates a second embodiment of the trimming;

FIG. 6A is a cross-sectional view of a heterostructure formed by way of a method according to one embodiment of the present disclosure;

FIG. 6B is a cross-sectional view of the formation of a weakened region in the heterostructure of FIG. 6A for delimiting therein a layer to be transferred;

FIG. 6C is a cross-sectional view of the bonding of the heterostructure of FIG. 6B to a receiver substrate;

FIG. 6D is a cross-sectional view of the layer transferred to the receiver substrate after detachment of the heterostructure of FIG. 6C along the weakened region;

FIG. 7A is a cross-sectional view of a heterostructure formed by way of a method according to one embodiment of the present disclosure;

FIG. 7B is a cross-sectional view of the formation of a weakened region in the heterostructure of FIG. 7A for delimiting therein a layer to be transferred;

FIG. 7C is a cross-sectional view of the bonding of the heterostructure of FIG. 7B to a receiver substrate; and

FIG. 7D is a cross-sectional view of the layer transferred to the receiver substrate after detachment of the heterostructure of FIG. 7C along the weakened region.

To make the figures clearer, the dimensions of the various elements have not necessarily been shown to scale.

Reference signs that are identical from one figure to the next denote elements that are identical or perform the same function, which are not necessarily described in detail again.

### DETAILED DESCRIPTION

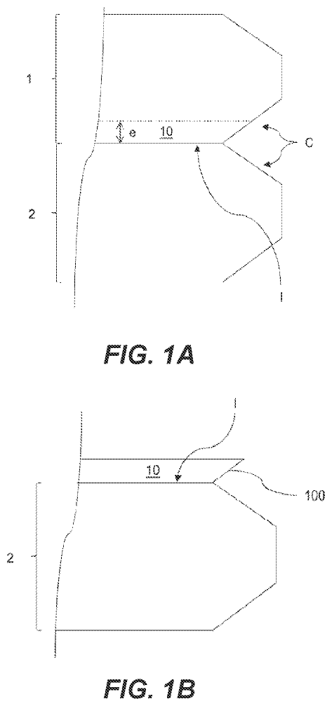

FIGS. 1A and 1B illustrate the problem that the present disclosure seeks to avoid during the production of a heterostructure intended in particular to perform the function of donor virtual substrate with a view to the later transfer of a portion of the donor virtual substrate to a receiver substrate.

The formation of the heterostructure comprises bonding a donor substrate 1 of a first material and a carrier substrate 2 of a second material.

The first material may be a material intended for later transfer to the donor substrate, but which exhibits, with the material of the receiver substrate, a difference in coefficient of thermal expansion that prevents direct transfer, as explained in the introduction. For example, but without limitation, the first material may be a piezoelectric material, such as lithium niobate (LiNbO₃), lithium tantalate (LiTaO₃), or a semiconductor material, such as gallium nitride (GaN), indium phosphide (InP), gallium arsenide (GaAs), etc.

The second material is generally different from the first material. The function of the carrier substrate is to temporarily support the donor substrate until a portion of the donor substrate is transferred to the receiver substrate. The second material may advantageously be chosen so as to exhibit, with the material of the receiver substrate, a small difference in coefficient of thermal expansion, i.e., typically a difference in coefficient of thermal expansion of zero or smaller than 5% in terms of absolute value. For example, but without limitation, the second material may be silicon, glass, quartz, sapphire, a ceramic, or polycrystalline aluminum nitride (AlN). The choice of the second material may be made according to the material of the receiver substrate to ensure that the coefficients of thermal expansion of the materials match. In one preferred embodiment, the second material is identical to that of the receiver substrate.

As illustrated in FIG. 1A, the substrates 1 and 2 each have a peripheral chamfer C on each of their main faces. In general, the chamfer has an angle of 22 to 40° with respect to the main surface of each substrate and extends over a height of the order of 200 to 300 μm in the direction of the thickness of the substrate and a width of the order of 200 to 300 μm in the radial direction of the substrate.

To form the heterostructure, the donor substrate 1 has to be thinned so as to transfer a layer 10 of thickness e to the carrier substrate 2. The thinning may be achieved by etching the donor substrate from the face opposite the bonding interface I with the carrier substrate 2. Particularly advantageously, the etching may be carried out in a number of steps, with increasing thinness. Thus, a first part of the donor substrate may be removed by coarse grinding, which allows the thickness of the donor substrate to be reduced rapidly. Next, finer grinding may be implemented to continue reducing the thickness of the donor substrate, while decreasing the roughness of the surface of the donor substrate. Lastly, chemical-mechanical polishing (CMP) may be carried out to smooth the surface of the thinned donor substrate so as to achieve the desired roughness. As mentioned further below, the fine grinding does not have to be performed directly after the coarse grinding and may be performed after another step of the method.

For example, the donor substrate 1 may have a thickness of the order of a few hundreds of micrometers, and the thinned donor substrate forming the layer 10 may have a thickness e of a few tens of micrometers, for example, between 10 and 100 μm, preferably between 10 and 50 μm.

In this case, as can be seen in FIG. 1A, the thickness e is smaller than the thickness of the chamfer C of the donor substrate.

Consequently, as illustrated in FIG. 1B, which shows the assembly of the donor substrate 1 and of the carrier substrate 2 after the thinning of the donor substrate, the thinned donor substrate forming the layer 10 has a peripheral edge 100 comprising a sharp angle at the level of the main face opposite the bonding interface I. Such a sharp angle is liable to break when the heterostructure is handled. This breaking effect, called “flaking,” is particularly harmful because the debris from the thinned donor substrate might contaminate the entire production line using the heterostructure.

To avoid such an effect, the present disclosure proposes removing a peripheral portion from the donor substrate, before or after the bonding of the donor substrate to the carrier substrate. Such removal will also be called “trimming” (“edge trimming” or “edge grinding”) in the present text.

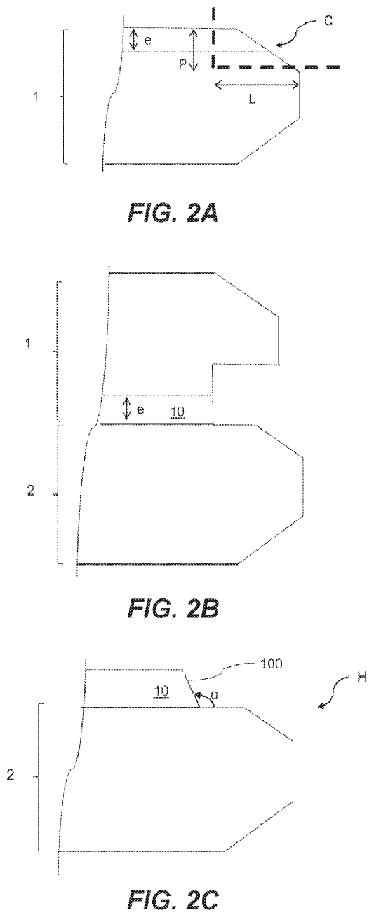

The trimming aims to remove the chamfer from the donor substrate, whether thinned or not, and to form a straight edge, preferably inclined by an angle α (shown in FIG. 2C) greater than or equal to 90° with respect to the main face of the carrier substrate in order to prevent any particles from getting stuck in the corner between the main face of the carrier substrate and the edge of the donor substrate. In the case of an obtuse angle (α>90°), an angle relatively close to 90°, for example, between 90 and 135°, will be chosen however, in order to prevent the layer subsequently transferred from the donor substrate to the receiver substrate from forming a brittle strip.

To that end, in some embodiments, the width of the removed portion peripheral (denoted by L in FIGS. 2A, 3A and 4A, which will be described further below) is greater than or equal to the width of the chamfer of the donor substrate.

Furthermore, as explained in detail further below, the width of the removed peripheral portion may depend on the mode of bonding of the donor substrate to the carrier substrate.

A first mode of bonding is bonding by molecular adhesion, in which the donor substrate and the carrier substrate, potentially covered with a layer of oxide, are in direct contact, adhesion being provided by intermolecular forces at the bonding interface, in particular van der Waals forces. In a manner known per se, such bonding may require preparation of the surfaces to be bonded, in particular polishing, cleaning, and/or plasma activation.

A second mode of bonding is bonding via a polymeric layer, as described in particular in document WO 2019/186032. The polymeric layer may be formed by depositing a photopolymerizable layer on the surface of at least one of the substrates, bonding the substrates via the photopolymerizable layer, and then irradiating the assembly with a light flux whose wavelength is chosen so as to have a low coefficient of absorption with respect to one of the substrates. Thus, the light flux passes through the substrate without being absorbed and reaches the adhesive layer, thereby allowing it to polymerize. For example, when the donor substrate is made of a piezoelectric material, the light flux may have a wavelength of between 320 and 365 nm and be applied through the donor substrate.

In practice, the polymeric layer may be formed as follows.

A photopolymerizable adhesive layer is deposited on the surface of at least one of the substrates. The photopolymerizable adhesive layer may advantageously be deposited by spin-coating. This technique consists in rotating the substrate on which the photopolymerizable layer is to be deposited on itself at a substantially constant and relatively high speed in order to spread the photopolymerizable layer uniformly over the entire surface of the substrate by centrifugal force. To this end, the substrate is typically placed and held by vacuum chuck on a turntable. A person skilled in the art is capable of determining the operating conditions, such as the volume of adhesive deposited on the surface of the substrate, the speed of rotation of the substrate, and the minimum deposition time according to the desired thickness for the adhesive layer. The thickness of the photopolymerizable adhesive layer deposited is typically between 2 μm and 8 μm.

According to one non-limiting example, the photopolymerizable adhesive layer sold under the reference “NOA 61” by NORLAND PRODUCTS may be used in the present disclosure.

The donor substrate and the carrier substrate are then bonded via the photopolymerizable layer to form a heterostructure. The bonding is preferably carried out at ambient temperature, i.e., at about 20° C. It is however possible to carry out the bonding hot at a temperature of between 20° C. and 50° C., and more preferably between 20° ° C. and 30° ° C. In addition, the bonding step is advantageously carried out under vacuum, which makes it possible to desorb water from the surfaces forming the bonding interface, i.e., the surface of the adhesive layer and the surface of the handle substrate or of the piezoelectric substrate.

The heterostructure is then subjected to irradiation with a light flux, in order to polymerize the adhesive layer. The light source is preferably a laser. The light radiation, or light flux, is preferably ultra-violet (UV) radiation. Depending on the composition of the adhesive layer, UV radiation having a wavelength of between 320 nm and 365 nm will preferably be chosen. The irradiation is carried out by exposing the free face of the donor substrate to the incident light radiation. Thus, the light radiation penetrates into the heterostructure from the free face of the donor substrate, passes through the donor substrate, until reaching the adhesive layer, thus causing the polymerization of the adhesive layer. The polymerization of the adhesive layer makes it possible to form a polymer layer that ensures the mechanical cohesion of the heterostructure, keeping the donor substrate and the carrier substrate bonded together.

The irradiation of the heterostructure gives rise to a thermal process via which the donor substrate, through which the radiation passes, is able to partially absorb the energy of the radiation and to heat up. Too much heating would be liable to destabilize the structure of the donor substrate if it is piezoelectric, which could lead to degradation of the physical and chemical properties of the piezoelectric layer. In addition, too much heating could cause the donor substrate and the carrier substrate to deform due to their difference in coefficient of thermal expansion. In order to avoid excessive heating of the donor substrate, the irradiation is advantageously pulsed, i.e., the heterostructure is exposed to a plurality of pulses of light rays. Each pulse lasts a set irradiation time, which may be equal or different from one pulse to the next. The pulses are spaced apart in time by a determined rest time during which the heterostructure is not exposed to light rays. Those skilled in the art will be able to determine the irradiation time of each pulse, the rest time between each pulse, and the number of pulses to be applied to completely polymerize the adhesive layer. Thus, for example, about ten pulses lasting 10 seconds each, separated by rest times also lasting 10 seconds each, could be implemented.

The polymerized adhesive layer therefore makes it possible to bond the donor substrate and the carrier substrate without exposing them to a thermal budget that would be liable to deform them, which makes it possible to endow the heterostructure with sufficient mechanical strength for the subsequent transfer of a piezoelectric layer. The thickness of the polymerized adhesive layer is preferably between 2 and 8 μm. This thickness depends in particular on the constituent material of the photopolymerizable adhesive layer deposited before bonding, on the thickness of the photopolymerizable adhesive layer, and on the experimental conditions of irradiation.

In one alternative embodiment, in particular when neither the donor substrate nor the carrier substrate is sufficiently transparent to the light flux required to polymerize the photopolymerizable layer, it is possible to use a polymeric adhesive that is able to polymerize under the effect of a low-temperature anneal (i.e., typically lower than 100° C.).

This second mode of bonding implementing a polymeric layer (whether it is polymerizable via irradiation or via low-temperature anneal) is particularly advantageous in the context of the present disclosure because it allows the width of the peripheral portion of the donor substrate to be reduced, and thereby the duration of the trimming operation to be shortened.

Specifically, in the case of bonding via a polymer layer, the width of the peripheral portion to be removed from the donor substrate may be between 300 and 1000 μm, preferably between 300 and 500 μm from the edge of the substrate. What is meant by the edge of the substrate in the present text is the outermost edge of the substrate, outside of the chamfered portion; in other words, the edge of the substrate defines the maximum diameter of the substrate.

In the case of a bonding by molecular adhesion, the width of the peripheral portion to be removed from the donor substrate may be between 1 and 3 mm, preferably between 2 and 3 mm from the edge of the donor substrate.

This difference in the trimmed width between the two modes of bonding is explained by the fact that, in the case of bonding by molecular adhesion, there is a peripheral ring that has, beyond the chamfer, a width of the order of 1 or 2 mm on which it is difficult to ensure continuous bonding between the two substrates. This means trimming the donor substrate over a width greater than or equal to this ring, so as to ensure continuous bonding over the entire surface of the substrates.

In the case of bonding via a polymer layer, bonding is provided continuously by the polymer layer up to the chamfer, which allows the donor substrate to be trimmed over a smaller width than in the case of bonding by molecular adhesion, this width potentially being just slightly greater than that of the chamfer. This means a less substantial loss of the first material.

Whatever the mode of bonding of the donor substrate to the carrier substrate, the trimming of the donor substrate may be carried out at various stages in the production of the heterostructure, the width of the removed peripheral portion being chosen according to the mode of bonding.

In a first embodiment, illustrated in FIGS. 2A-2C, trimming is performed before the bonding of the donor substrate to the carrier substrate.

FIG. 2A schematically illustrates the operation of trimming the donor substrate before bonding to the carrier substrate, the thick dashed lines delimiting the peripheral portion removed during trimming. In this operation, it is not necessary to trim through the entire thickness of the donor substrate. Specifically, since the donor substrate is intended to be thinned after bonding thereof to the carrier substrate, it is enough to trim over a depth P greater than the target thickness e of the donor substrate after thinning, from the face of the donor substrate that is intended to be bonded to the carrier substrate. Furthermore, as explained above, the width L of the removed peripheral portion is greater than the width of the chamfer C.

FIG. 2B is a cross-sectional view of the periphery of the heterostructure after the bonding of the trimmed donor substrate 1 of FIG. 2A to the carrier substrate 2. Although no bonding layer is shown in this figure, a polymeric layer as described above may be used to achieve the bonding between the two substrates, as an alternative to bonding by molecular adhesion.

The portion of the donor substrate resulting from the thinning and defining the layer 10 to be transferred is delimited schematically by a dashed line, the line representing the surface of the donor substrate after thinning.

FIG. 2C is a cross-sectional view of the periphery of the heterostructure after thinning of the donor substrate. It is therefore observed that, unlike the case of FIG. 1B, the edge 100 of the thinned donor substrate (or transferred layer 10) forms a right or obtuse angle with respect to the surface of the carrier substrate and is therefore less liable to break.

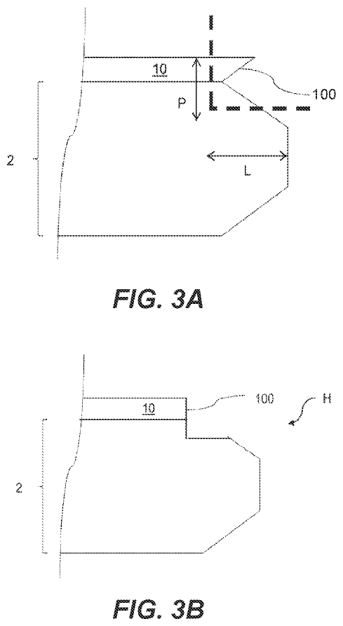

In a second embodiment, illustrated in FIGS. 3A and 3B, trimming is performed after bonding and the thinning of the donor substrate on the carrier substrate.

FIG. 3A schematically illustrates the trimming of the thinned donor substrate (or transferred layer 10) on the carrier substrate 2 (the donor substrate having been bonded to the carrier substrate beforehand and then thinned to the desired thickness). Although no bonding layer is shown in this figure, a polymeric layer as described above may be used to achieve the bonding between the two substrates, as an alternative to bonding by molecular adhesion.

The thick dashed lines delimit the peripheral portion removed during trimming. In this operation, the trimming is carried out over a depth P at least equal to the thickness of the thinned donor substrate (or transferred layer 10). Preferably, the trimming extends at least partly into the thickness of the carrier substrate 2. Specifically, even if the surface of the carrier substrate exhibits roughness resulting from the trimming operation, this is not detrimental inasmuch as this surface is not intended to be bonded to the receiver substrate in the later use of the heterostructure as donor virtual substrate. Furthermore, as explained above, the width L of the removed peripheral portion is greater than the width of the chamfer C.

Potentially, trimming may be carried out when the donor substrate has been only partly thinned. Thus, for example, the donor substrate may undergo a first step of thinning via coarse grinding, followed by the trimming step and a second step of thinning via fine grinding or chemical-mechanical polishing, allowing the roughness of the surface of the thinned donor substrate to be reduced. This particular order of the steps allows trimming to be carried out while the donor substrate is still thick enough not to be at risk of damage, in particular at risk of loss of cohesion of the donor substrate during trimming. For example, in the case of a piezoelectric donor substrate, it is advantageous to retain a thickness of 60 μm after the course grinding in order to carry out the trimming, and then to carry out the fine grinding to reach a thickness of the order of 10 to 20 μm.

FIG. 3B is a cross-sectional view of the periphery of the heterostructure after thinning of the donor substrate. It is therefore observed that, unlike the case of FIGS. 1B and 3A, the edge 100 of the thinned donor substrate (or transferred layer 10) forms a right (or obtuse) angle with the surface of the carrier substrate and is therefore less liable to break.

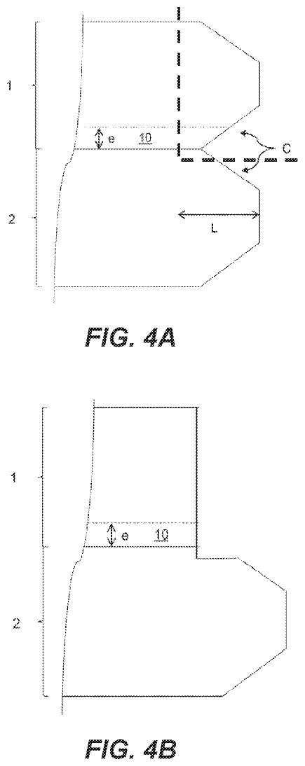

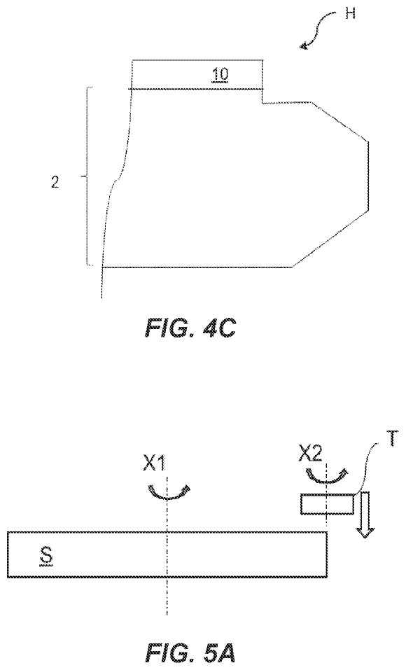

In a third embodiment, illustrated in FIGS. 4A-4C, trimming is performed between bonding and the thinning of the donor substrate on the carrier substrate.

FIG. 4A schematically illustrates the operation of trimming the donor substrate after bonding thereof to the carrier substrate, but before the thinning of the donor substrate (the donor substrate having been bonded to the carrier substrate beforehand and then thinned to the desired thickness). Although no bonding layer is shown in this figure, a polymeric layer as described above may be used to achieve the bonding between the two substrates, as an alternative to bonding by molecular adhesion.

The thick dashed lines delimit the peripheral portion removed during trimming. Unlike the embodiment of FIGS. 2A and 2B, trimming is performed through the entire thickness of the donor substrate 1. Preferably, the trimming also extends at last partly into the thickness of the carrier substrate 2. Specifically, even if the surface of the carrier substrate exhibits roughness resulting from the trimming operation, this is not detrimental inasmuch as this surface is not intended to be bonded to the receiver substrate in the later use of the heterostructure as donor virtual substrate. Furthermore, as explained above, the width L of the removed peripheral portion is greater than the width of the chamfer C.

FIG. 4B is a cross-sectional view of the periphery of the donor substrate before thinning thereof and of the carrier substrate after the trimming of FIG. 4A.

FIG. 4C is a cross-sectional view of the periphery of the heterostructure after thinning of the donor substrate. It is therefore observed that, unlike the case of FIG. 1B, the edge 100 of the thinned donor substrate, which forms the transferred layer 10, forms a right (or obtuse) angle with the surface of the carrier substrate and is therefore less liable to break.

There exist various techniques for carrying out the trimming.

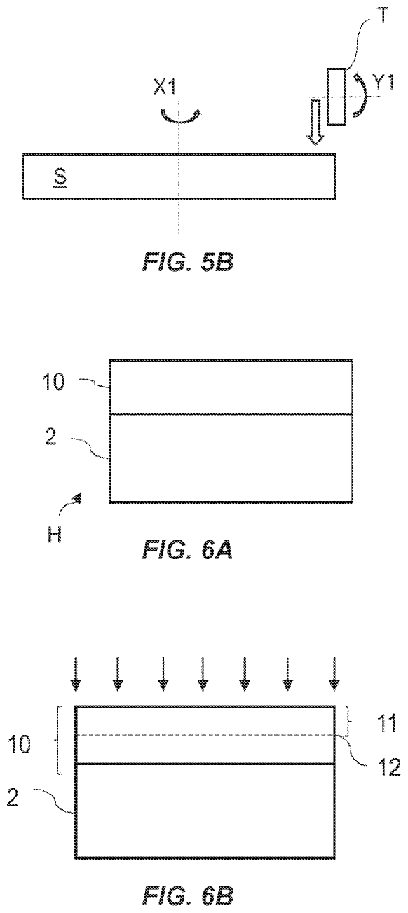

According to a first embodiment, illustrated in FIG. 5A, the substrate or the assembly of substrates intended to be trimmed is positioned on a support S rotated about the axis X1 of revolution of the substrate or of the assembly of substrates. A cutting tool T, such as an abrasive wheel, for example, a diamond wheel, is rotated about an axis X2 parallel to the axis X1 and is arranged to face the peripheral portion to be removed. The tool is gradually moved toward the substrate or the assembly of substrates in a direction parallel to the axis X1 (represented by the arrow), in order to gradually grind away the material of the substrate or of the assembly of substrates that it encounters.

According to a second embodiment, illustrated in FIG. 5B, the substrate or the assembly of substrates intended to be trimmed is positioned on a support S rotated about the axis X1 of revolution of the substrate or of the assembly of substrates. A cutting tool T, such as an abrasive wheel, is rotated about an axis Y1 perpendicular to the axis X1 and is brought toward the peripheral portion to be removed. The tool is gradually moved toward the substrate or the assembly of substrates in a direction parallel to the axis X1, in order to gradually grind away the material of the substrate or of the assembly of substrates that it encounters. Potentially, depending on the width of the peripheral portion to be removed, the tool T may also be moved in a direction parallel to the axis Y1 in order to gradually grind away the material of the substrate or of the assembly of substrates that it encounters in the radial direction.

Whichever embodiment is used, the effect of the trimming is to locally harden the material ground by the tool, such that the exposed surface after trimming may exhibit a certain roughness or defects. It may then be advantageous to carry out polishing, for example, chemical-mechanical polishing (CMP), to remove the hardened region and improve the surface state of the donor substrate, in order to prevent bonding defects during the subsequent transfer to a receiver substrate.

The heterostructure thus formed is used as a donor virtual substrate to transfer a portion of the donor substrate to a receiver substrate. By virtue of its edge forming a right or obtuse angle with respect to the surface of the carrier substrate, the thinned donor substrate is much less brittle and may be comfortably handled to implement the transfer method.

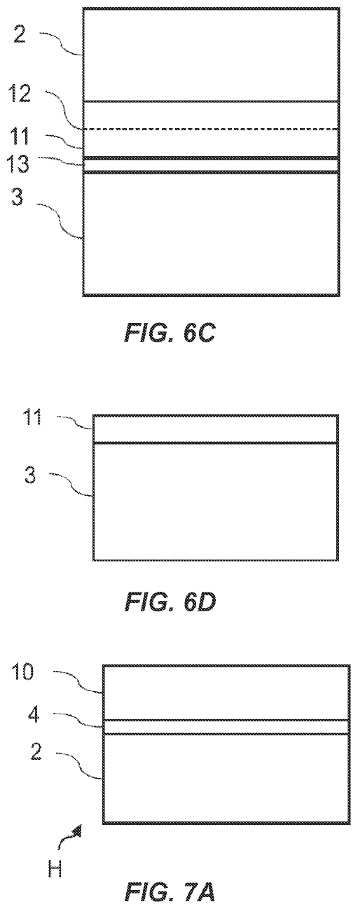

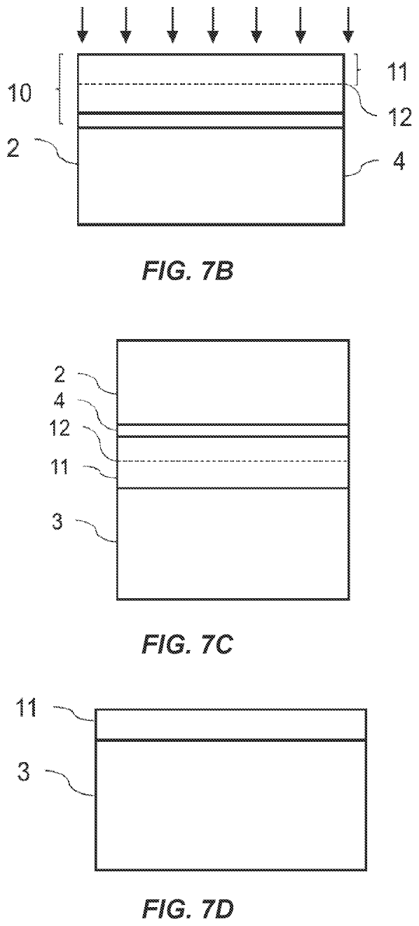

Now described, with reference to FIGS. 6A-6D and 7A-7D, are two embodiments of a method for transferring a layer from the heterostructure to a receiver substrate.

The receiver substrate may be chosen according to the electrical and/or thermal properties of the final structure comprising the transferred layer and the receiver substrate. For example, the receiver substrate may comprise silicon, glass, quartz, sapphire, a ceramic, and/or polycrystalline aluminum nitride. In some embodiments, in particular regarding substrates for radiofrequency applications, the receiver substrate may be a silicon substrate comprising a charge-trapping layer, for example, a layer of polycrystalline silicon, or potentially of silicon carbide, of amorphous silicon and/or of porous silicon.

Particularly advantageously, the carrier substrate and the receiver substrate may be made of materials exhibiting a difference in coefficient of thermal expansion that is smaller than or equal to 5% in terms of absolute value, so as to allow balancing of the stresses on either side of the thinned donor substrate during the transfer process, thereby preventing deformation of the thinned donor substrate. Preferably, the carrier substrate and the receiver substrate may be formed of one and the same material.

With reference to FIG. 6A, a heterostructure H is provided that comprises a thinned donor substrate 10 trimmed according to any one of the embodiments described above, and a carrier substrate 2, the substrates being bonded by molecular adhesion. To simplify the figures, the trimmed portion of the donor substrate and, where applicable, of the carrier substrate has not been shown. The width of the trimmed portion is typically between 1 and 3 mm, preferably between 2 and 3 mm from the edge of the donor substrate.

With reference to FIG. 6B, atomic species, such as hydrogen and/or helium are implanted into the thinned donor substrate 10 in order to form a weakened region 12, which delimits a layer 11 of the first material.

With reference to FIG. 6C, the heterostructure (on the side of the layer 11 to be transferred) is bonded to the receiver substrate 3. In some embodiments, an intermediate layer 13 is formed on the heterostructure and/or the receiver substrate. The intermediate layer may have the function of improving the strength of bonding and/or of contributing to the electrical and/or thermal properties of the final structure. For example, the intermediate layer may comprise silicon oxide, silicon nitride, silicon oxynitride, aluminum nitride (AlN), or tantalum oxide (Ta₂O₅), or a stack of at least two of these materials. In other embodiments, the intermediate layer is omitted and there is direct bonding between the heterostructure and the receiver substrate.

Potentially, a heat treatment is implemented with a view to increasing the bonding energy.

With reference to FIG. 6D, the thinned donor substrate 10 is detached along the weakened region 12, so as to transfer the layer 11 of the first material to the receiver substrate.

With reference to FIG. 7A, a heterostructure H is provided that comprises a thinned donor substrate 10 trimmed according to any one of the embodiments described above, and a carrier substrate 2, the substrates being bonded by a polymeric layer 4. To simplify the figures, the trimmed portion of the donor substrate and, where applicable, of the carrier substrate has not been shown. The width of the trimmed portion is typically between 300 and 1000 μm, preferably between 300 and 500 μm from the edge of the donor substrate.

With reference to FIG. 7B, atomic species, such as hydrogen and/or helium, are implanted into the thinned donor substrate 10 in order to form a weakened region 12, which delimits a layer 11 of the first material.

With reference to FIG. 7C, the heterostructure (on the side of the layer 11 to be transferred) is bonded to the receiver substrate 3. Although no intermediate layer is illustrated between the heterostructure and the receiver substrate, an intermediate layer as described with reference to FIG. 6C may be formed at the interface.

Potentially, a heat treatment is implemented with a view to increasing the bonding energy. The heat treatment is advantageously carried out at a temperature lower than 300° ° C. to avoid damaging the polymer layer.

With reference to FIG. 7D, the thinned donor substrate 10 is detached along the weakened region 12 so as to transfer the layer 11 of the first material to the receiver substrate 3.

Using one of these transfer methods, it is possible in particular to form a piezoelectric-on-insulator structure comprising, in succession, a piezoelectric thin layer having a thickness of the order of a few micrometers, a silicon oxide layer, a charge-trapping layer and a silicon substrate.

1. A method of transferring a layer from a heterostructure to a receiver substrate, comprising:
providing a donor substrate of a first material and a carrier substrate of a second material;
bonding the donor substrate to the carrier substrate;
thinning the donor substrate, so as to form the heterostructure comprising the thinned donor substrate on the carrier substrate;
removing a peripheral portion from the donor substrate;
forming a weakened region in the thinned donor substrate so as to delimit a layer of the first material to be transferred;
bonding the heterostructure to a receiver substrate, the layer of the first material to be transferred being located at the bonding interface; and
detaching the donor substrate along the weakened region so as to transfer the layer of the first material to the receiver substrate.

2. The method of claim 1, wherein the removing of the peripheral portion from the donor substrate is carried out before the bonding of the donor substrate to the carrier substrate.

3. The method of claim 1, wherein the removing of the peripheral portion from the donor substrate is carried out after the bonding of the donor substrate to the carrier substrate.

4. The method of claim 3, wherein the removing of the peripheral portion from the donor substrate further comprises removing a peripheral portion from the carrier substrate.

5. The method of claim 3, wherein the removing of the peripheral portion from the donor substrate is carried out after the donor substrate has been at least partly thinned.

6. The method of claim 1, wherein the donor substrate is bonded to the carrier substrate via a polymeric bonding layer.

7. The method of claim 6, wherein a width of the peripheral portion removed from the donor substrate is between 300 and 1000 μm from the edge of the donor substrate.

8. The method of claim 1, wherein the bonding of the donor substrate to the carrier substrate comprises bonding the donor substrate to the carrier substrate via molecular adhesion.

9. The method of claim 8, wherein a width of the peripheral portion removed from the donor substrate is between 1 and 3 mm from the edge of the donor substrate.

10. The method of claim 1, wherein the removing of the peripheral portion from the donor substrate comprises:
placing the donor substrate on a carrier that is rotatably movable about a first axis; and
machining the donor substrate using an abrasive wheel rotating about a second axis parallel to the first axis, the abrasive wheel further being driven in translation along the second axis.

11. The method of claim 1, wherein the removing of the peripheral portion from the donor substrate comprises:
placing the donor substrate on a carrier that is rotatably movable about a first axis; and
machining the donor substrate using an abrasive wheel rotating about a second axis perpendicular to the first axis.

12. The method of claim 1, further comprising polishing the donor substrate after the removing of the peripheral portion from the donor substrate.

13. The method of claim 1, wherein the donor substrate comprises a piezoelectric material or a semiconductor material.

14. The method of claim 1, wherein a thickness of the thinned donor substrate is between 10 and 100 μm.

15. The method of claim 1, wherein the carrier substrate comprises at least one material selected from among silicon, glass, quartz, sapphire, a ceramic, or polycrystalline aluminum nitride.

16. The method of claim 1, further comprising, before the bonding of the heterostructure to the receiver substrate, forming an intermediate layer is on at least one of the donor substrate or the receiver substrate.

17. The method of claim 16, wherein the intermediate layer comprises one or more materials selected from among silicon oxide, silicon nitride, silicon oxynitride, aluminum nitride, or tantalum oxide, or a stack of layers formed of at least two of the one or more materials.

18. The method of claim 1, wherein the receiver substrate comprises at least one material selected from among silicon, glass, quartz, sapphire, a ceramic, or polycrystalline aluminum nitride.

19. The method of claim 18, wherein the receiver substrate is a silicon substrate including a charge-trapping layer comprising at least one material selected from among polycrystalline silicon, silicon carbide, amorphous silicon or porous silicon.

20. The method of claim 1, wherein the carrier substrate and the receiver substrate comprise materials exhibiting a difference in coefficient of thermal expansion smaller than or equal to 5% in terms of absolute value.

21. The method of claim 20, wherein the carrier substrate and the receiver substrate are formed of one and the same material.

22. The method of claim 1, wherein a thickness of the transferred layer is between 30 nm and 1.5 μm.
